(19) United States
(12) Patent Application Publication
(10) Pub. No.: US 2021/0027227 A1
(43) Pub. Date: Jan. 28, 2021

(54) ENERGY MANAGEMENT SYSTEM

(71) Applicant: TOYOTA JIDOSHA KABUSHIKI KAISHA, Toyota-shi (JP)

(72) Inventors: Takao INATA, Setagaya-ku (JP); Ikuo OHTA, Toyota-shi (JP); Hideshi MIZUTANI, Toyota-shi (JP); Atsushi SAJIKI, Okazaki-shi (JP); Yohei TANIGAWA, Toyota-shi (JP); Atsushi NAKAJIMA, Kariya-city (JP); Atsuo KOMATSUBARA, Nagakute-shi (JP)

(21) Appl. No.: 16/931,584

(22) Filed: Jul. 17, 2020

(30) Foreign Application Priority Data
Jul. 26, 2019 (JP) 2019-137777

(51) Int. Cl. G06Q 10/06; H02J 7/00; G06Q 50/06; G06Q 30/02; G01R 19/25

(52) U.S. Cl. CPC G06Q 10/06315; H02J 7/0047; G01R 19/2513; G06Q 10/0637; G06Q 30/0205; G06Q 50/06

(57) ABSTRACT

An energy management system for enabling an airport including a power storage facility to prepare an electric power purchase plan in order to purchase a predetermined amount of electric power from an electric power company for a predetermined period and to cover electric power to be used at the airport. The energy management system includes an acquisition unit configured to acquire arrival and departure information and information about climate change, a prediction unit configured to predict a fluctuation in the demand for the electric power at the airport based on the arrival and departure information and the information about climate change, and a determination unit configured to determine the predetermined amount of electric power and the predetermined period based on the fluctuation in demand for electric power and a power storage capacity of the power storage facility.

### CROSS REFERENCE TO RELATED APPLICATIONS

This application is based upon and claims the benefit of priority from Japanese patent application No. 2019-137777, filed on Jul. 26, 2019, the disclosure of which is incorporated herein in its entirety by reference.

### BACKGROUND

The present disclosure relates to an energy management system.

In many cases, power storage facilities are installed at airports to supply power in emergencies such as disasters. As an energy storage system, a battery and a hydrogen energy storage system that converts electric power into hydrogen to be stored are known. Japanese Unexamined Patent Application Publication No. 2013-032271 discloses a technique related to a system for continuously generating hydrogen at a low cost.

### SUMMARY

Commonly, when a predetermined amount of electric power is constantly supplied from an electric power company for a predetermined period, it is considered that electric power can be purchased at a lower price than when a different amount of electric power is supplied each day. This is because when a different amount of electric power is supplied each day, the electric power company needs to ensure the power supply capability corresponding to the user's peak power consumption, and thus the charge is based on the user's peak power consumption. For this reason, for a user whose demand for electric power fluctuates greatly, there is a problem that a charge becomes higher than the electric power actually used.

As described above, airports often have power storage facilities such as batteries and hydrogen energy storage systems for power supply in the event of an emergency such as a disaster. However, the infrastructure for these power storage facilities are expensive and require various expenditures such as those for inspection and maintenance. For this reason, there has been a demand for a method for effectively utilizing these power storage facilities not only in emergencies but also in normal times at an airport.

The present disclosure has been made in view of the above circumstances. An object of the present disclosure is to provide an energy management system which enables an airport including a power storage facility to prepare an electric power purchase plan for purchasing a predetermined amount of electric power from an electric power company for a predetermined period and to cover an amount of electric power used at the airport for the predetermined period.

An example aspect of the present disclosure is an energy management system for enabling an airport including a power storage facility to prepare an electric power purchase plan in order to purchase a predetermined amount of electric power from an electric power company for a predetermined period and to cover electric power to be used at the airport. The energy management system includes: an acquisition unit configured to acquire arrival and departure information and information about climate change; a prediction unit configured to predict a fluctuation in the demand for the electric power at the airport based on the arrival and departure information and the information about climate change; and a determination unit configured to determine the predetermined amount of electric power and the predetermined period based on the fluctuation in demand for electric power and a power storage capacity of the power storage facility.

The arrival and departure information and the information about climate change include factors that largely affect the fluctuation in the demand for the electric power at the airport. Thus, the fluctuation in the demand for the electric power at the airport is predicted based on the arrival and departure information and the information about climate change, so that an accurate prediction can be made. When the fluctuation in the demand for electric power at the airport can be obtained, the amount of electric power predicted to be used at the airport can be calculated with high accuracy. For example, the amount of electric power to be purchased from the electric power company can be determined so that it becomes greater than or equal to the calculated amount of electric power predicted to be used at the airport, and so that the amount of electric power to be purchased from the electric power company can be determined to be less than or equal to the power storage capacity of the power storage facility of the airport. The amount of electric power purchased from the electric power company is the product of the predetermined amount of electric power and the predetermined period. Thus, the predetermined amount of electric power and the predetermined period can be determined based on the prediction of the fluctuation in the demand for the electric power in the airport and the power storage capacity of the power storage facility.

Further, the determination unit may be configured to determine the predetermined amount of electric power and the predetermined period so that an amount of electric power to be purchased, which is a product of the predetermined amount of electric power and the predetermined period, exceeds an amount of actual electric power consumption at the airport calculated based on the fluctuation in the demand for the electric power. As described above, the amount of electric power to be purchased from the electric power company can be determined so that it becomes greater than or equal to the calculated amount of electric power expected to be used at the airport, and so that the amount of electric power to be purchased from the electric power company can be determined to be less than or equal to the power storage capacity of the power storage facility of the airport. The amount of electric power to be purchased from the electric power company is the product of the predetermined amount of electric power and the predetermined period. Thus, the predetermined amount of electric power and the predetermined period can be determined based on the prediction of the fluctuation in the demand for the electric power at the airport and the power storage capacity of the power storage facility.

Furthermore, the determination unit may be configured to consider demand for electric power in a neighboring area of the airport in determining the predetermined amount of electric power. The demand for electric power in the neighboring area of the airport is considered, and, for example, the electric power purchased at a relatively low price is stored in the surplus power storage capacity of the power storage facility, and then the electric power stored in the surplus power storage capacity is supplied to the neighboring area of the airport at a unit price with a little margin on the purchase unit price. By doing so, the surplus power storage capacity in the power storage facility can be effectively utilized.

According to the present disclosure, it is possible to enable an airport including a power storage facility to prepare an electric power purchase plan for purchasing a predetermined amount of electric power from an electric power company for a predetermined period and to cover an amount of electric power used at the airport for the predetermined period.

The above and other objects, features and advantages of the present disclosure will become more fully understood from the detailed description given hereinbelow and the accompanying drawings which are given by way of illustration only, and thus are not to be considered as limiting the present disclosure.

### BRIEF DESCRIPTION OF DRAWINGS

FIG. 1 is a block diagram showing a configuration of an energy management system according to an embodiment;

FIG. 2 is a flowchart showing a flow of processing for preparing an electric power purchase plan in the energy management system according to this embodiment;

FIG. 3 is a schematic diagram for explaining a method for determining a predetermined amount of electric power and a predetermined period based on a prediction of a fluctuation in demand for electric power in the electric power purchase plan; and

FIG. 4 is a schematic diagram for explaining a method for determining a predetermined amount of electric power and a predetermined period in consideration of the electric power demand in a neighboring area.

### DESCRIPTION OF EMBODIMENTS

The present disclosure will be described below through an embodiment of the disclosure, but the disclosure according to the claims is not limited to the following embodiment. Further, not all of the configurations described in the embodiment are essential as means for solving the problem. In order to clarify the description, the following descriptions and drawings have been omitted and simplified as appropriate. In the drawings, the same elements are denoted by the same reference signs, and repeated descriptions are omitted as necessary.

First, a configuration of an energy management system according to this embodiment will be described. The energy management system according to this embodiment prepares an electric power purchase plan for allowing an airport including a power storage facility to purchase a predetermined amount of electric power from an electric power company for a predetermined period, so that the amount of electric power used at the airport for the predetermined period can be covered.

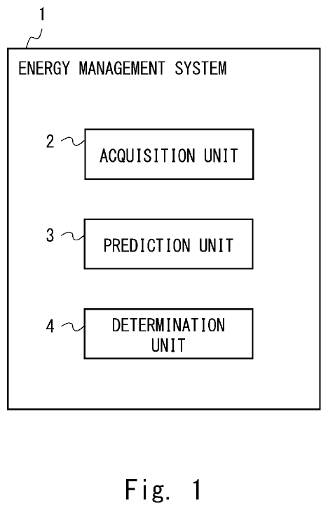

FIG. 1 is a block diagram showing a configuration of the energy management system 1. As shown in FIG. 1, the energy management system 1 includes an acquisition unit 2, a prediction unit 3, and a determination unit 4.

The acquisition unit 2 acquires arrival and departure information and information about climate change. The prediction unit 3 predicts a fluctuation in the demand for electric power in an airport based on the arrival and departure information and the information about climate change. The number of flights to and from the airport and climate change have a large influence on the fluctuations in the demand for electric power at the airport. The demand for electric power at airports is greater when there are more flights than when there are fewer. Demand for electric power at airports is higher in summer and winter than in spring and autumn. Thus, the fluctuation in the demand for electric power at the airport is predicted based on the arrival and departure information and the information about climate change, so that an accurate prediction can be made. The determination unit 4 determines a predetermined amount of electric power and a predetermined period based on the demand fluctuation and the power storage capacity of the power storage facility.

Next, a flow of processing for preparing an electric power purchase plan in the energy management system 1 will be described below. In the following descriptions, FIG. 1 is also referred to as appropriate.

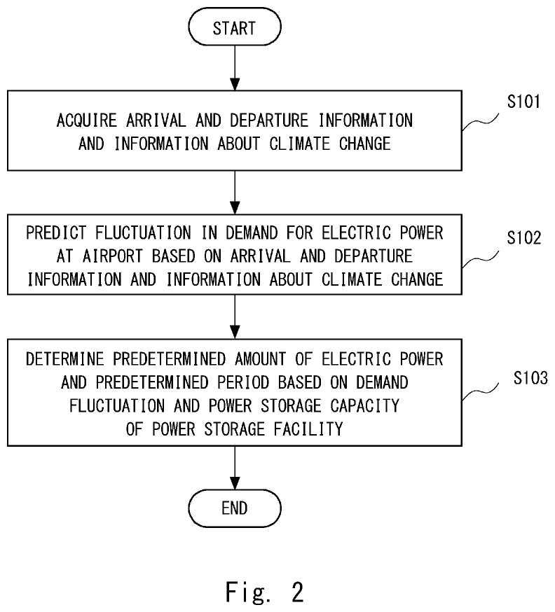

FIG. 2 is a flowchart showing a flow of processing for preparing an electric power purchase plan in the energy management system 1. As shown in FIG. 2, first, the acquisition unit 2 acquires the arrival and departure information and information about climate change (Step S101). Next, the prediction unit 3 predicts a fluctuation in the demand for electric power at the airport based on the arrival and departure information and the information about climate change (Step S102). Next, the determination unit 4 determines a predetermined amount of electric power and a predetermined period based on the demand fluctuation and the power storage capacity of the power storage facility (Step S103).

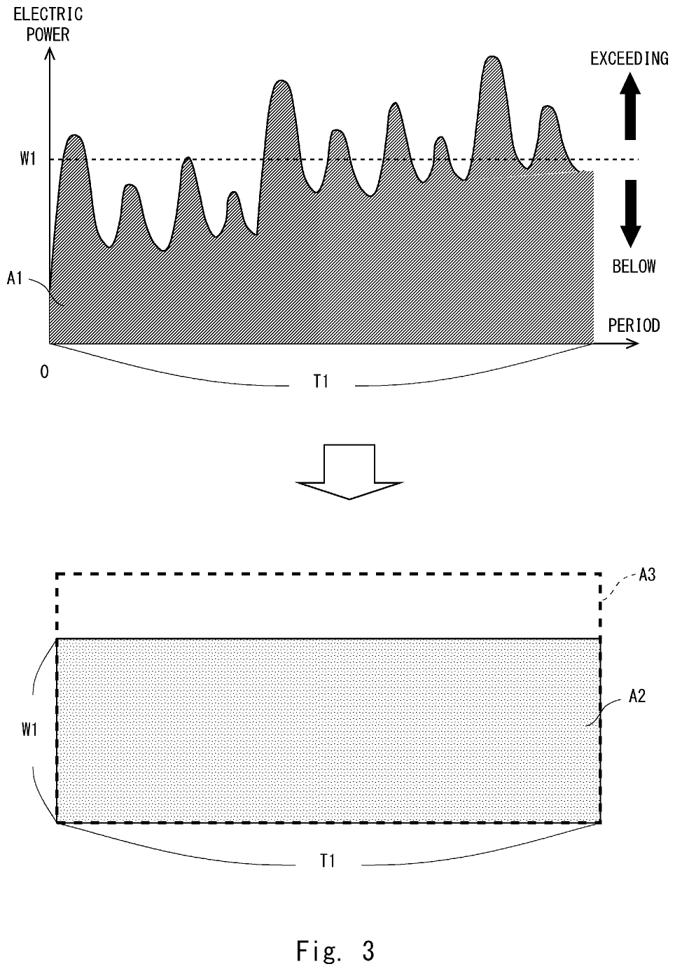

FIG. 3 is a schematic diagram for explaining a method for determining a predetermined amount of electric power and a predetermined period based on the prediction of a fluctuation in the demand for electric power in the electric power purchase plan. The upper part of FIG. 3 shows a prediction of a fluctuation in demand for electric power in an airport for a certain period. As shown in the upper part of FIG. 3, an area A1 obtained by integrating the fluctuation in the demand for the electric power in a certain period T1 with time is an amount of electric power (amount of actual electric power consumption) predicted to be used at the airport during the period T1. In this way, when a fluctuation in demand for electric power at an airport in a certain period can be predicted, the amount of electric power predicted to be used at the airport during the period can be calculated.

The lower part of FIG. 3 shows an amount of electric power to be purchased from an electric power company during a predetermined period. Here, a period T1 during which the fluctuation in the demand for electric power at the airport is predicted is defined as “predetermined period”. When the predetermined amount of electric power is W1, as shown in the lower part of FIG. 3, the amount of electric power to be purchased is an area A2, which is a product of the predetermined amount of electric power W1 and the predetermined period T1. Note that an area A3 of the part surrounded by the broken line is the power storage capacity of the power storage facility of the airport.

In the prediction of a fluctuation in demand for electric power at the airport shown in the upper part of FIG. 3, when the electric power predicted to be used at the airport is less than the predetermined amount of electric power W1, a surplus amount of electric power obtained by subtracting the amount of electric power predicted to be used at the airport from the amount of electric power supplied from the electric power company to the airport is stored in the power storage facility. On the other hand, when the amount of electric power predicted to be used at the airport exceeds the predetermined amount of electric power W1, the electric power supplied from the electric power company alone is not enough, and thus shortage in the electric power must be covered by the electric power stored in the power storage facility of the airport.

Thus, the area A2 (hereinafter referred to as an amount of electric power to be purchased A2) corresponding to the amount of electric power to be purchased shown in the lower part of FIG. 3 must be larger than or equal to the area A1 (hereinafter referred to as an amount of actual electric power consumption A1) corresponding to the amount of actual electric power consumption shown in the upper part of FIG. 3. That is, the determination unit 4 (see FIG. 1) determines the predetermined amount of electric power W1 and the predetermined period T1 so that the amount of electric power to be purchased exceeds the amount of actual electric power consumption. If the prediction of the fluctuation in the demand for electric power is accurate, the amount of actual electric power consumption can also be predicted with high accuracy, so that a necessary and sufficient amount of electric power can be purchased.

As shown in the lower part of FIG. 3, the area A3 (hereinafter referred to as a power storage capacity A3) corresponding to the power storage capacity of the power storage facility of the airport must be larger than or equal to the amount of electric power to be purchased A2. Note that when the power storage capacity A3 of the power storage facility at the airport is larger than the amount of electric power to be purchased A2, the power storage facility at the airport may be reviewed, for example, by reducing the power storage capacity of the power storage facility at the airport.

As shown in the lower part of FIG. 3, when the power storage capacity A3 of the power storage facility of the airport is sufficiently larger than the amount of electric power to be purchased A2, the surplus power storage capacity may be used to supply electric power to a neighboring area of the airport. The surplus power storage capacity is obtained by subtracting the amount of electric power to be purchased A2 expected to be stored from the power storage capacity A3. In other words, the determination unit 4 (see FIG. 1) may consider the demand for electric power in the neighboring area of the airport when determining the predetermined amount of electric power and the predetermined period.

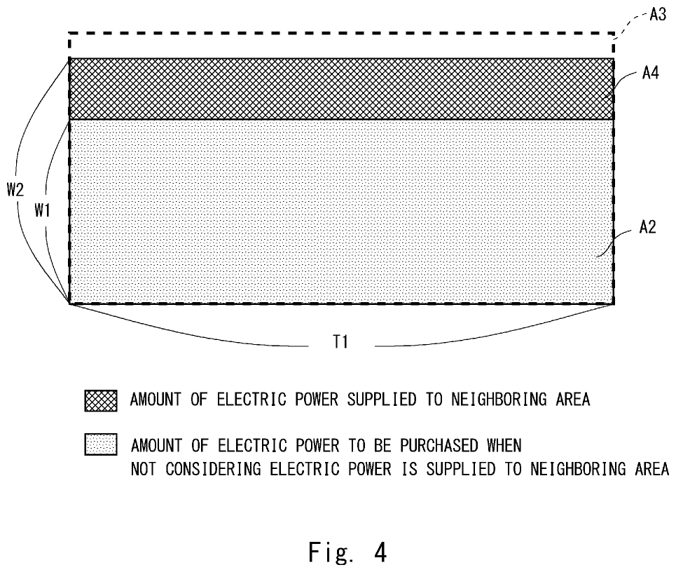

FIG. 4 is a schematic diagram for explaining a method for determining a predetermined amount of electric power and a predetermined period in consideration of demand for electric power in a neighboring area. As shown in FIG. 4, when the amount of electric power corresponding to the area A4 is supplied to the neighboring area of the airport, the predetermined amount of electric power is determined as W2 (W2>W1). As described with reference to FIG. 3, A2 is the amount of electric power to be purchased when it is not considered that electric power is supplied to the neighboring area of the airport, while W1 is the predetermined amount of electric power when the amount of electric power to be purchased is A2.

It is necessary to make the sum of the amount of electric power to be purchased A2, which is an amount of electric power when it is considered that no electric power is supplied to the neighboring area of the airport, and the amount of electric power A4 equal to or less than the power storage capacity A3 (A3>A2+A4). When a predetermined amount of electric power is constantly supplied for a predetermined period, the electric power can be purchased at a relatively low price. Thus, the electric power purchased at a relatively low price is stored in the surplus power storage capacity of the power storage facility, and the electric power stored in the surplus power storage capacity is supplied to the neighboring area of the airport at a unit price with a little margin on the purchase unit price. By doing so, the surplus power storage capacity in the power storage facility can be effectively utilized.

Note that the present disclosure is not limited to the above-described embodiment, and may be appropriately modified without departing from the scope thereof.

For example, in the above-described embodiments, the energy management system according to the present disclosure has been described as a hardware configuration, but the present disclose is not limited thereto. In the present disclosure, any processing of the energy management system can be achieved by a processor, such as a CPU (Central Processing Unit), loading and executing a computer program stored in a memory.

The program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g. magneto-optical disks), CD-ROM (compact disc read only memory), CD-R (compact disc recordable), CD-R/W (compact disc rewritable), and semiconductor memories (such as mask ROM, PROM (programmable ROM), EPROM (erasable PROM), flash ROM, RAM (random access memory), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g. electric wires, and optical fibers) or a wireless communication line.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. An energy management system for enabling an airport including a power storage facility to prepare an electric power purchase plan in order to purchase a predetermined amount of electric power from an electric power company for a predetermined period and to cover electric power to be used at the airport, the energy management system comprising:
an acquisition unit configured to acquire arrival and departure information and information about climate change;
a prediction unit configured to predict a fluctuation in the demand for the electric power at the airport based on the arrival and departure information and the information about climate change; and
a determination unit configured to determine the predetermined amount of electric power and the predetermined period based on the fluctuation in demand for electric power and a power storage capacity of the power storage facility.

2. The energy management system according to claim 1, wherein
the determination unit is configured to determine the predetermined amount of electric power and the predetermined period so that an amount of electric power to be purchased obtained by a product of the predetermined amount of electric power and the predetermined period exceeds an amount of actual electric power consumption at the airport calculated based on the fluctuation in demand for electric power.

3. The energy management system according to claim 1, wherein
the determination unit is configured to consider demand for electric power in a neighboring area of the airport in determining the predetermined amount of electric power.
